(19) United States
(12) Patent Application Publication
(10) Pub. No.: US 2007/0158471 A1
(43) Pub. Date: Jul. 12, 2007

(54) Nozzle apparatus for organic light emitting device

(76) Inventors: Joon-Yong Park, Yongin-si (KR); Sang-Yeol Kim, Gwacheon-si (KR); Sung-Hun Lee, Seoul (KR)

Correspondence Address: Robert E. Bushnell, Suite 300, 1522 K Street, N.W., Washington, DC, 20005-1202, US

(21) Appl. No.: 11/513,095

(22) Filed: Aug. 31, 2006

(30) Foreign Application Priority Data
Jan. 6, 2006 (KR) 10-2006-0001673

(51) Int. Cl. A01G 27/00; B05B 1/32

(52) U.S. Cl. 239/451; 239/456; 239/67

(57) ABSTRACT

A nozzle apparatus for an organic light emitting device. The nozzle apparatus includes a nozzle and a pressure regulator. The nozzle discharges organic solution onto a substrate. The pressure regulator controls a discharging quantity of the organic solution through the nozzle. The discharging quantity of the organic solution is minutely controlled through adjusting a length of the nozzle. Therefore, the nozzle apparatus can precisely achieve a small amount of low-viscosity organic solution being discharged onto a substrate to form an organic layer with reduced thickness and narrow width.

### CLAIMS OF PRIORITY

This application makes reference to, incorporates the same herein, and claims all benefits accruing under 35 U.S.C.§119 from an application for NOZZLE APPARATUS FOR ORGANIC LIGHT EMITTING DEVICE earlier filed in the Korean Intellectual Property Office on 6 Jan. 2006 and there duly assigned Serial No. 10-2006-0001673.

### BACKGROUND OF THE INVENTION

1. Field of the Invention

The present invention relates to nozzle apparatus for an organic light emitting device, and more particularly, to a nozzle apparatus for an organic light emitting device capable of precisely controlling the minute quantities of low viscosity organic solution that is discharged from the nozzle.

2. Description of the Related Art

A light emitting device is an emissive display with not only a wide viewing angle and superb contrast, but also a quick response. Light emitting devices include inorganic light emitting devices that use inorganic compounds as emissive layers, and organic light emitting devices that use organic compounds. Because organic light emitting devices have better brightness, driving voltage, and quicker response characteristics than inorganic light emitting devices, as well as multi-color capability, they are the object of much research and development.

Such an organic light emitting device includes a plurality of organic film layers, such as a light emitting layer, a hole injection layer, and a hole transfer layer. Techniques for patterning these organic film layers on a substrate include a deposition technique using a shadow mask, an inkjet technique, a dispensing technique and a photolithographic technique.

When a dispensing technique is used to form the organic film layer, a highly accurate pattern can be obtained. The dispensing technique generally uses a nozzle apparatus that includes a pressure regulator, a cylinder, and a nozzle. Specifically, the nozzle apparatus uses the pressure regulator to pressurize organic solution contained inside the cylinder so that it can be discharged through the nozzle to the outside. Here, the pressure regulator can be a gas or a liquid pressure regulator.

Organic solution used to form the organic film layer, however, has a low viscosity, so that the nozzle apparatus must control its discharging at minute quantities in order to form a thin organic film layer having a narrow line width. That is, if the amount of organic solution that is discharged increases, the discharged organic solution spreads over a wide area on a substrate, and the organic layer that is formed becomes a thick film with a wide line width. Because the quantity of discharged organic solution is controlled by the pressure regulator, the pressure regulator must be capable of reliable operation at low pressure ranges in order to accurately control the discharging of minute quantities of organic solution. However, conventional commercial gas pressure regulators cannot reliably regulate the organic solution at pressures below 5 Kpa. Accordingly, what is needed is a reliable apparatus for regulating the discharge of organic solution in minute quantities.

### SUMMARY OF THE INVENTION

It is therefore an object of the present invention to provide an improved nozzle apparatus for discharging organic solution.

It is also an object of the present invention to provide a nozzle apparatus capable of producing thin and narrow organic layers by providing for careful regulation of discharge flow at low flow rates.

It is still an object of the present invention to provide a nozzle apparatus for an organic light emitting device capable of precisely controlling the discharge of low viscosity organic solution in minute quantities.

It is further an object of the present invention to provide a nozzle apparatus for an organic light emitting device capable of reducing the thickness of an organic film formed on a substrate and slimming the line width thereof

These and other objects can be achieved by providing a nozzle apparatus for an organic light emitting device that includes a nozzle adapted to discharge a solution and a pressure regulator adapted to control a discharging quantity of the solution through the nozzle, wherein the discharging quantity of the solution is controlled by adjusting a length of the nozzle. The nozzle can include a plurality of bent portions. The nozzle can include a zig-zag portion. The nozzle can include a spiral portion. The nozzle can include a serpentine portion. The nozzle can be of a straight shape. The pressure regulator can be a gas pressure regulator. The nozzle apparatus can also include a cylinder adapted to hold the solution, wherein the pressure regulator is adapted to pressurize the solution held in the cylinder so that the solution can be discharged through the nozzle. The pressure regulator can be a liquid pressure regulator. The nozzle apparatus can further include a nozzle conveyor adapted to move the nozzle. The nozzle can include a plurality of curved portions. The nozzle can be attached to the cylinder by a nozzle connector, a distance between the nozzle connector and a substrate onto which the solution is deposited can be 1 mm and a length of the nozzle can be in excess of 10 mm. A length of displacement of solution through the nozzle can be 1 mm and a length of the nozzle can be in excess of 10 mm.

### BRIEF DESCRIPTION OF THE DRAWINGS

A more complete appreciation of the invention and many of the attendant advantages thereof, will be readily apparent as the same becomes better understood by reference to the following detailed description when considered in conjunction with the accompanying drawings in which like reference symbols indicate the same or similar components, wherein:

FIG. 1 is a schematic perspective view of a nozzle apparatus used to form patterned organic film layers for an organic light emitting device according to an embodiment of the present invention;

FIG. 2 is a schematic sectional view of the nozzle portion in FIG. 1; and

FIGS. 3A through 3D show various embodiments of the nozzle portion in FIG. 1 according to the present invention.

### DETAILED DESCRIPTION OF THE INVENTION

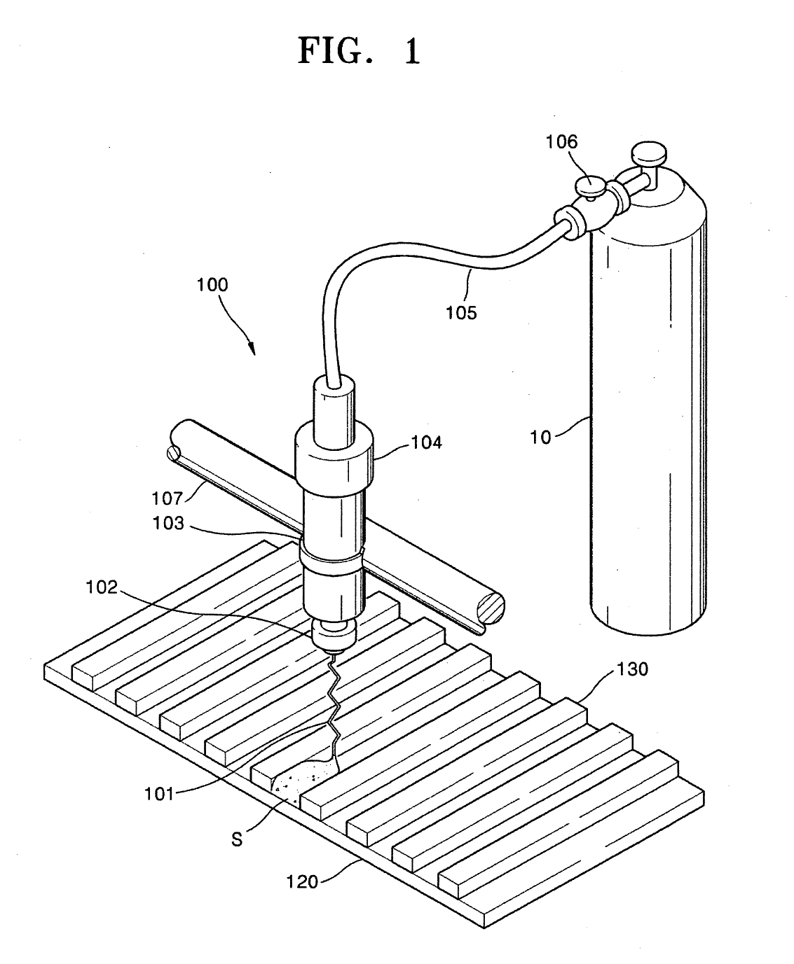

Turning now to the figures, FIG. 1 is a schematic perspective view of a nozzle apparatus used to form patterned organic film layers for an organic light emitting device according to an embodiment of the present invention. Referring to FIG. 1, nozzle apparatus 100 for an organic light emitting device according to an embodiment of the present invention includes a pressure regulator 106 coupled to a gas storage tank 10, a gas supply line 105, a cylinder 103 holding organic solution (S), a nozzle 101, and a nozzle conveyor 107.

The gas storage tank 10 contains pressurized air or nitrogen, etc. The gas in the gas storage tank 10 is regulated at an adequate pressure by the pressure regulator 106 to flow through the gas supply line 105 and enter the cylinder 103 containing a predetermined organic solution (S). Here, the organic solution (S) can be a solution containing red, green, or blue light emitting substances that form a light emitting layer, and can be a solution containing other organic substances that form other layers such as a hole injection layer or a hole transfer layer. In this embodiment, the organic solution (S) is depicted as being discharged through the nozzle 101 by means of gas pressure, however the present invention is not limited thereto as the organic solution can instead be pressurized and discharged through the nozzle 101 by means of a micro pump or a liquid pressure regulator (not shown).

The gas supply line 105 is coupled to the cylinder 103 through the gas supply line connector 104, where said coupling can be a screw-type coupling. The nozzle 101 is coupled to the cylinder 103 through a nozzle connector 102, where said coupling can also be a screw-type coupling. The nozzle conveyor 107 is coupled to allow the cylinder 103 or nozzle 101 so that the nozzle 101 can move with respect to the substrate 120. The nozzle 101 in this embodiment is bent in a zig-zag shape, which extends for the overall length of the nozzle 101 within the given installation space, so that the amount of organic solution (S) discharged through the nozzle 101 can be controlled at low flow rates.

The principle of minutely adjusting the discharged amount of organic solution (S) by adjusting the length of the nozzle 101 will be described in detail below. As stated above, gas pressure regulators are not able to reliably control pressures below 5 Kpa. Therefore, it is difficult to minimize the thickness of the organic layer and minimize its line width below a predetermined critical value using a dispenser. In order to make the organic layer thin and slim, the amount of organic solution (S) discharged from the nozzle 101 must be reduced, which necessitates reducing the pressure of gas that enters the cylinder 103 and pressurizes the organic solution (S) within the cylinder 103. However, because gas pressure regulators 106 are limited in their ability to lower their operating pressure and reliably maintain a constant low pressure as stated above, another technique must be employed to reduce the discharged amount of organic solution (S) below a predetermined level.

For this purpose, the following equation that reflects Poiseuille's Law should be considered.

Q=π(P_{O}−P_{L})R⁴/(8μL) Equation 1

In the above equation, Q is the volume flow rate (or the discharged amount of organic solution S), P_{O} is the pressure at the intake portion of the nozzle 101, P_{L} is the pressure at the discharge portion of the nozzle 101 (P₀-P_{L} term includes the driving force from the head difference), R is the inner diameter (ID) of the nozzle 101, μ is the viscosity of the organic solution (S), and L is the length of the nozzle 101.

In the equation, one technique of reducing the discharged flow rate Q is to increase μ. However, by increasing the viscosity of the organic solution (S), the thickness of the applied organic layer increases, so that it is difficult to create a thin layer. A second technique of reducing Q is to reduce R. However, when the inner diameter of the nozzle 101 is reduced, the nozzle 101 can become blocked. A third technique of reducing Q is to lower P_{O}. However, this technique is linked to the problem of a gas pressure regulator's 106 inability to reliably operate at low pressures, and is therefore not a viable solution at present.

A fourth technique of reducing Q is to lengthen L. When the length of the nozzle 101 is increased, problems that can arise are as follows: 1) a limited installation space for the nozzle apparatus 100 prevents the lengthening, and 2) μ can be increased by a resulting drag force in the bending. In this embodiment, problem 1) is solved by bending the nozzle 101 a plurality of times. Problem 2) is shown empirically not to be a major problem. The embodiment involving a technique of increasing the length L of the nozzle 101 will be described below.

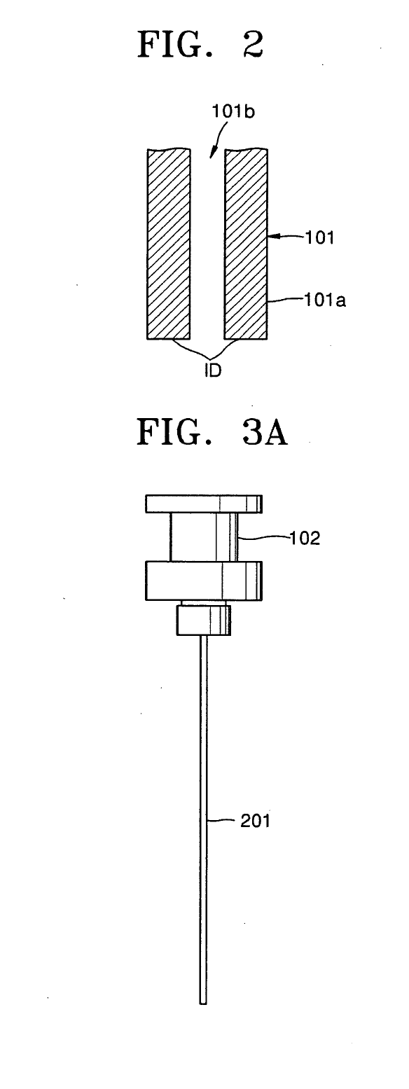

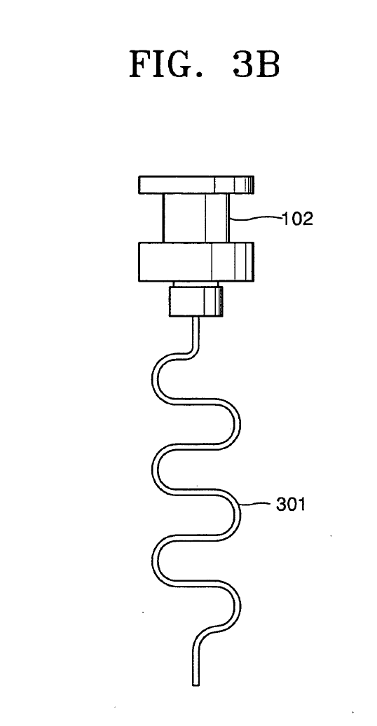

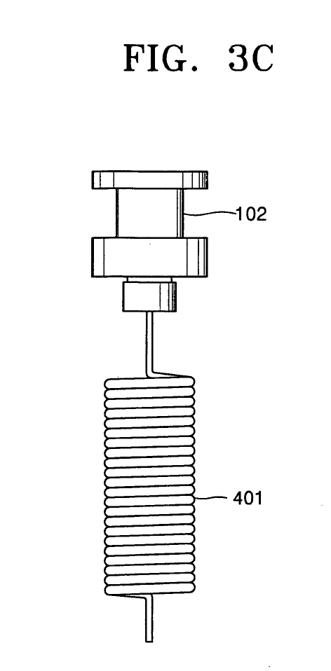

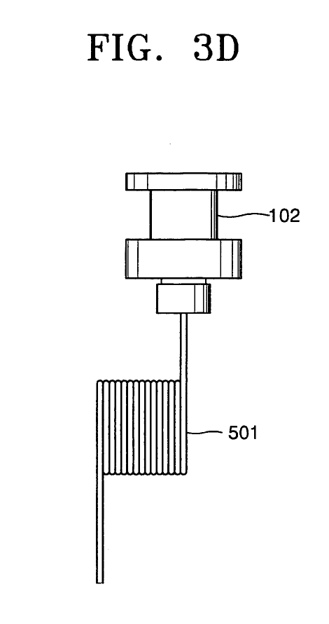

Turning now to FIGS, 2 through 3D, FIG. 2 is a schematic sectional view of the nozzle 101 in FIG. 1, and FIGS. 3A through 3D show various embodiments of the nozzle portion in FIG. 1 according to the present invention. Like reference numbers in FIG. 1 denote like components in FIGS. 2 through 3D.

Referring to FIG. 2, the nozzle 101 includes a side wall 101a and a discharge hole 101b between side walls 101a. The diameter of the discharge hole 101b is the inner diameter (ID) of the nozzle 101. Organic solution (S) is discharged to the outside of the nozzle 101 through the discharge hole 101b. In this embodiment, the end of the discharge hole 101b is depicted as rectangular, however its shape is not so limited and can instead adopt various other shapes including a trapezoid.

In FIG. 3A, the nozzle 201 is of an alternate shape. That is, the nozzle 201 is formed in a straight shape. This type of straight nozzle 201 is difficult to make very long due to the restrictions of the installation space. FIG. 3B shows a nozzle 301 bent in a serpentine shape. FIGS. 3C and 3D show respective nozzles 401 and 501 bent in spiral shapes. The nozzle formed on the nozzle apparatus of the present invention is not limited to the embodiments shown in FIGS. 2 through 3D and can adopt other designs of alternative lengths and shapes. The notion behind the designs of the nozzles of FIGS. 3A through 3D is that the length L of the nozzle can be made long despite the limited space between the cylinder 103 and the substrate 120. By making L longer, Q, the flow rate can be made smaller resulting in the ability to form thin and narrow lines of organic material.

A detailed description of the operation of the above nozzle apparatus 100 will now be given. First, a light-emitting substance such as organic solution (S) is manually or automatically filled into the cylinder 103. Then, the nozzle apparatus 100 is moved by the nozzle conveyor 107 to a location on the substrate 120 on which the organic solution (S) is to be applied.

Next, the gas in the gas storage tank 10 is discharged at a predetermined pressure by means of the gas pressure regulator 106 through the gas supply line 105 into the cylinder 103. The gas that enters the cylinder 103 pressurizes the organic solution (S) inside the cylinder 103 to push the solution towards the nozzle 101. Thus, the organic solution (S) is discharged through the nozzle 101 and applied onto a predetermined region of the substrate 120. Specifically, the organic solution (S) is shown in FIG. 1 to be applied between the insulating layers 130, however the present invention is not so limited as the organic solution (S) can be applied to various other regions of the substrate 120. Additionally, while the organic solution (S) is applied on a predetermined region of the substrate 120, the nozzle 101 moves at a uniform speed across the substrate 120.

Empirical results of line width and line thickness were measured by varying one of nozzle length and nozzle speed and the results are listed below in chart 1. In the first experiment, the nozzle length was varied while holding the nozzle conveying speed constant. This first experiment was done for various nozzle speeds. In this first experiment, the nozzle 101 is straight when the length thereof is short, and the nozzle 101 is of a zig-zag shape when the length thereof is long. A gas pressure regulator is used as a commercial gas pressure regulator 106. A 0.8% wt of green light emitting substance made by Dow Chemical Co. was dissolved in m-xylene solvent and it was applied as the organic solution (S) on the substrate 120.

In the second experiment, the nozzle speed was varied while holding the nozzle length constant. The resultant line width and thickness of the discharged organic solution was then measured. This second experiment was conducted at various nozzle lengths. The consolidated results for both the first and the second experiments are listed in chart 1 below. For both experiments, when the length of the nozzle 101 was increased, its inner diameter was also increased to prevent blockage of the nozzle's 101 discharge hole 101b by the increase in length thereof. The remaining factors in the tests were the same as in the other test runs.

### [Chart 1]

| | Nozzle Specifications | | | | |
|---|---|---|---|---|---|
| | | Nozzle | Nozzle | Size of Organic Layer | |
| Test | | Inner | Conveying | Formed | |
| Run | Nozzle | Diameter | Speed | Thickness | Line Width |
| Number | Length (mm) | (μm) | (mm/sec) | (Å) | (μm) |
| 1st | 1 | 100 | 70 | 680 | 470 |
| 2nd | 1 | 100 | 100 | 590 | 391 |
| 3rd | 1 | 100 | 200 | 500 | 382 |
| 4th | 13 | 140 | 70 | 200 | 331 |
| 5th | 13 | 140 | 100 | 290 | 386 |
| 6th | 13 | 140 | 200 | 210 | 360 |

Effects of Extending Nozzle Length (First Experiment)

In order to measure the effects of a reduced thickness and line width of an organic layer formed on a substrate 120 when the length of the nozzle 101 is extended, the conveying speed of the nozzle 101 must be the same in each instance. Below, cases in which the nozzle 101 conveying speed is the same are compared as in the first experiment.

Comparison of First and Fourth Runs. With the nozzle 101 conveying speed held constant at 70 mm/sec, the thickness and line width of the formed organic layer were drastically reduced from 680 to 200 Å, and 470 to 331 μm, respectively when the length of the nozzle was increased from 1 mm to 13 mm.

Comparison of Second and Fifth Runs. With the nozzle 101 conveying speed held constant at 100 mm/sec, the thickness of the formed organic layer was drastically reduced from 590 to 290 Å and the line width was only marginally reduced from 391 to 386 μm when the length of the nozzle was increased from 1 mm to 13 mm.

Comparison of Third and Sixth Runs. With the nozzle 101 conveying speed held constant at 200 mm/sec, the thickness of the formed organic layer was drastically reduced from 500 to 210 Å and the line width was only marginally reduced from 382 to 360 μm when the length of the nozzle was increased from 1 mm to 13 mm.

Analysis of Test Results. When comparing the results of six the test runs, the thickness and line width of the organic layer formed was drastically reduced by extending the length of the nozzle 101 from 1 to 13 mm. In order to extend the length of the nozzle 101 while minimizing the installation space it requires, the nozzle 101 can be bent or curved a plurality of times. This produces unforeseen results described below and revealed by the second experiment.

First, in the first through third test runs, where a very short straight nozzle 101 of 1 mm in length is conveyed at speeds of 70, 100, and 200 mm/sec, respectively, the thickness of the organic layer is 680, 590, and 500 Å, respectively, and its line width is 470, 391, and 382 μm, respectively. Accordingly, the test results in these cases matched reasonable expectations that line width and line thickness decrease with increased nozzle speed. This is because it can be generally expected that the amount of organic solution applied to certain portions on the substrate 120 decreases as the conveying speed of the nozzle 101 increases and thus the thickness and the line width and line thickness of the formed organic layer is reduced.

Next, when a nozzle 101 length is 13 mm as in the fourth through sixth test runs while being conveyed at a speeds of 70, 100, and 200 mm/sec, respectively, the thickness of the organic layer increases from 200 to 290 Å, and then becomes thinner again to 210 Å, respectively and the line width of the organic layer increases from 331 to 386 μm and then decreases again to 360 μm, respectively. Accordingly, the test results here show results not anticipated by reasonable expectations. The unexpected results appear to be on account of the drag force created by bending the nozzle 101 to make it 13 mm in length in a confined space. However, despite the unintended results, by extending and bending the length of the nozzle 101, the organic layer formed on the substrate can still be formed thinner and narrower in accordance with the intentions of the present invention.

The present invention provides a nozzle apparatus for an organic light emitting device that precisely controls small quantities of low viscosity organic solution that is discharged. The present invention also provides a nozzle apparatus for an organic light emitting device that reduces the thickness and line width of an organic layer formed on a substrate.

While the present invention has been particularly shown and described with reference to exemplary embodiments thereof, it will be understood by those of ordinary skill in the art that various changes in form and details can be made therein without departing from the spirit and scope of the present invention as defined by the following claims.

What is claimed is:

1. A nozzle apparatus, comprising:
a nozzle adapted to discharge a solution; and
a pressure regulator adapted to control a discharging quantity of the solution through the nozzle, wherein the discharging quantity of the solution is controlled by adjusting a length of the nozzle.

2. The nozzle apparatus of claim 1, wherein the nozzle includes a plurality of bent portions.

3. The nozzle apparatus of claim 2, wherein the nozzle includes a zig-zag portion.

4. The nozzle apparatus of claim 2, wherein the nozzle includes a spiral portion.

5. The nozzle apparatus of claim 2, wherein the nozzle includes a serpentine portion.

6. The nozzle apparatus of claim 1, wherein the nozzle is of a straight shape.

7. The nozzle apparatus of claim 1, wherein the pressure regulator is a gas pressure regulator.

8. The nozzle apparatus of claim 7, further comprising a cylinder adapted to hold the solution, wherein the pressure regulator is adapted to pressurize the solution held in the cylinder so that the solution can be discharged through the nozzle.

9. The nozzle apparatus of claim 1, wherein the pressure regulator is a liquid pressure regulator.

10. The nozzle apparatus of claim 1, further comprising a nozzle conveyor adapted to move the nozzle.

11. The nozzle apparatus of claim 1, wherein the nozzle includes a plurality of curved portions.

12. The nozzle apparatus of claim 8, the nozzle being attached to the cylinder by a nozzle connector, a distance between the nozzle connector and a substrate onto which the solution is deposited being 1 mm and a length of the nozzle being in excess of 10 mm.

13. The nozzle apparatus of claim 1, a length of displacement of solution through the nozzle being 1 mm and a length of the nozzle being in excess of 10 mm.

14. The nozzle apparatus of claim 1, a length of displacement of solution through the nozzle being 1 mm and a length of the nozzle being in excess of 10 mm.
